(19) United States
(12) Patent Application Publication
(10) Pub. No.: US 2023/0369028 A1
(43) Pub. Date: Nov. 16, 2023

(54) Wear Compensating Confinement Ring

(71) Applicant: Lam Research Corporation, Fremont, CA (US)

(72) Inventors: Adam Christopher Mace, Morgan Hill, CA (US); Shahriar Memaran, Richmond, CA (US); Robert Charatan, Portland, OR (US); Siwon Jang, Pleasanton, CA (US)

(21) Appl. No.: 18/250,740

(22) PCT Filed: Oct. 30, 2020
(86) PCT No.: PCT/US2020/058394

§ 371 Date: Apr. 26, 2023

(51) Int. Cl. H01J 37/32

(52) U.S. Cl. CPC H01J 37/32642; H01J 2237/332

(57) ABSTRACT

A confinement ring for use in a plasma processing chamber includes a lower horizontal section, a vertical section, and a upper horizontal section. The lower horizontal section extends between an inner lower radius and an outer radius of the confinement ring, and includes an extension section that extends vertically downward at the inner lower radius. A plurality of slots is defined in the lower horizontal section, wherein each slot extends radially from an inner diameter to an outer diameter along the lower horizontal section. An inner slot radius of each slot at the inner diameter is defined to be less than an outer slot radius at the outer diameter. The upper horizontal section extends between an inner upper radius and the outer radius of the confinement ring, and the vertical section integrally continues the lower horizontal section to the upper horizontal section at the outer radius of the confinement ring.

### TECHNICAL FIELD

The invention relates to a confinement ring used in a semiconductor process module.

### BACKGROUND

In semiconductor processing, a substrate undergoes various operations to form features that define integrated circuits. For example, for a deposition operation, the substrate is received into a processing chamber and, depending on type of feature to be formed, specific types of reactive gases are supplied to the chamber and a radio frequency power is applied to generate plasma. The substrate is received on a substrate support defined on a lower electrode, such as an electro static chuck. An upper electrode, such as a showerhead, is used to provide the specific types of reactive gases into the process chamber. A radio frequency power is applied to the reactive gases through a corresponding match network to generate the plasma used to selectively deposit ions over a surface of the substrate to form microscopic features. The reactive gases generate by-products, such as particulates and gases, etc., which need to be promptly removed from the plasma chamber in order to maintain the integrity of the microscopic features formed on the surface of the substrate.

To confine the generated plasma within a process region, a set of confinement rings are defined to surround the process region. Further, to improve the yield and to ensure the bulk of the plasma is over the substrate received for processing, the confinement rings surrounding the plasma region may be designed to extend the process region so as to cover not only the region above the substrate but also the region over an edge ring disposed to surround the substrate, when received for processing, and an outer confinement ring disposed adjacent to the edge ring. The set of confinement rings not only act to confine the plasma within the process region but also act to protect the inside structure of the processing chamber, including chamber walls.

During plasma processing, by-products and neutral gas species generated in the plasma are promptly removed so that the integrity of the microscopic features can be maintained. To efficiently remove the by-products and neutral gas species, the set of confinement rings may include a plurality of slots that are defined uniformly along a bottom side. Currently, these slots have wear issue due to constant exposure of the slots to the reactive plasma and due to the constant gas flow of the neutral gas species. The wearing of the slots is uneven along the length of the slots. The uneven slot wear results in the plasma going unconfined. When the plasma is unconfined, it can cause sparks in the portion of the chamber outside of the process region and damage chamber parts exposed to the unconfined plasma. Further, due to the uneven slot wear, the confinement ring needs to be replaced, even when other portions of the slots have sufficient usage life left.

It is in this context that embodiments of the invention arise.

### SUMMARY

Various implementations of the invention define a design of a confinement ring used in a plasma processing chamber for confining plasma within a plasma region. The design includes using tapered slot geometry to define slots in a bottom portion of the confinement ring. The slots are used to remove the by-products and neutral gas species generated within the plasma region while efficiently confining the plasma in the plasma region. Due to constant exposure to the plasma, the slots experience wear. When the wear reaches critical dimension, the confinement ring needs to be replaced to ensure plasma unconfinement does not occur. Due to limited space between slots, the area around the slots needs to be efficiently managed to maximize usage life of the confinement ring. However, due to the variance in the volume of plasma near the inner diameter of the slot as opposed to the outer diameter, the area of the slot at the inner diameter wears out more than the area at the outer diameter. Thus, in order to prevent uneven wear and to avoid having to replace the confinement ring due to the area of the slot at the inner diameter reaching the critical dimension faster than the outer diameter, a tapered slot geometry is used to define the slots. The tapered slot geometry makes efficient use of the area around the slot by defining a narrow end at the inner diameter and a broader end at the outer diameter. As the slot wears due to exposure to the plasma, the narrow end approaches the critical dimension at about the same time as the broader end, resulting in the entire slot width reaching the critical confinement dimension for the entire length at end of life. The tapered slot geometry makes efficient use of the area around the slot—especially at the outer diameter, thereby extending the usage life of the confinement ring while maintaining efficient plasma confinement within the plasma region. Consequently, the cost associated with the consumable confinement ring is lowered as the number of process cycles the confinement ring can be used in the plasma processing chamber is extended.

In one implementation, a confinement ring is disclosed. The confinement ring includes a lower horizontal section, an upper horizontal section, and a vertical section. The lower horizontal section extends between an inner lower radius and an outer radius of the confinement ring. The lower horizontal section includes an extension section that extends vertically downward at the inner lower radius. A plurality of slots is defined in the lower horizontal section. Each slot of the plurality of slots extends radially from an inner diameter to an outer diameter along the lower horizontal section. Each slot has an inner slot radius at the inner diameter that is less than an outer slot radius at the outer diameter leading to a narrow end at the inner diameter and a broader end at the outer diameter. The upper horizontal section extends between an inner upper radius and the outer radius of the confinement ring. The vertical section is disposed between the lower horizontal section and the upper horizontal section at the outer radius of the confinement ring to integrally continue the lower horizontal section to the upper horizontal section.

In one implementation, a difference in the inner slot radius and the outer slot radius of each slot defines a slot taper, such that each slot tapers down from the outer diameter to the inner diameter. The inner slot radius and the outer slot radius influencing the slot taper are sized to be an inverse of a wear rate at the corresponding inner diameter and the outer diameter of the slot.

In one implementation, the inner upper radius is greater than the inner lower radius of the confinement ring.

In one implementation, a step is defined on a top surface of the upper horizontal extension proximal to the inner upper radius. The step extends down from the top surface and out toward the inner upper radius of the confinement ring.

In one implementation, the inner diameter of the slot is greater than an inner ring diameter defined by the inner lower radius, and the outer diameter of the slot is less than an outer ring diameter defined by the outer radius of the confinement ring.

In one implementation, a top surface of the upper horizontal section includes a plurality of holes. Each hole of the plurality of holes is configured to receive a portion of a fastener means for securing the confinement ring to an upper electrode of a plasma processing chamber.

In one implementation, the extension section of the lower horizontal section is configured to rest on a radio frequency gasket defined on a top surface of a lower electrode of a plasma processing chamber.

In one implementation, the lower horizontal section, the upper horizontal section and the vertical section define a C-shaped structure configured to confine plasma generated in a plasma processing chamber.

In one implementation, a ratio of the inner slot radius to the outer slot radius is between about 1:1.1 and about 1:1.5.

In one implementation, an apparatus for confining plasma within a plasma processing chamber is disclosed. The plasma processing chamber includes a lower electrode for supporting a substrate and an upper electrode disposed over the lower electrode. The apparatus comprises a confinement ring. The confinement ring includes a lower horizontal section, an upper horizontal section and a vertical section. The lower horizontal section extends between an inner lower radius and an outer radius of the confinement ring. The lower horizontal section includes an extension section that extends vertically downward at the inner lower radius. A plurality of slots is defined in the lower horizontal section. Each slot of the plurality of slots extends radially from an inner diameter to an outer diameter along the lower horizontal section. Each slot has an inner slot radius at the inner diameter that is less than an outer slot radius at the outer diameter. The upper horizontal section extends between an inner upper radius and the outer radius of the confinement ring. The vertical section is disposed between the lower horizontal section and the upper horizontal section at the outer radius to integrally continue the lower horizontal section to the upper horizontal section. The extension section of the lower horizontal section is configured to surround a ground ring defined in the lower electrode.

In one implementation, the lower horizontal section, the vertical section and the upper horizontal section of the confinement ring define a C-shaped structure that is configured to confine plasma in a plasma region defined in the plasma processing chamber.

In one implementation, the extension section of the lower horizontal section of the confinement ring is configured to rest on a radio frequency gasket disposed on a top surface of an outer ring disposed adjacent to a ground ring defined in the lower electrode.

In one implementation, a height of the vertical section of the confinement ring is defined by a separation distance defined between the upper electrode and the lower electrode of the plasma processing chamber, when the plasma processing chamber is engaged for plasma processing.

In one implementation, the lower horizontal section, the vertical section and the upper horizontal section of the confinement ring form part of a confined chamber volume that extends radially outward between the lower electrode and upper electrode to define extended plasma processing region, when the confinement ring is installed in the plasma processing chamber.

In one implementation, the extension section is integral with the lower horizontal section, the vertical section and the upper horizontal section of the confinement ring. The extension section is configured to extend vertically below a lower surface of the lower horizontal section.

In one implementation, each of the plurality of slots is configured to define a path for gases out of a confined volume formed by the confinement ring, when the plasma processing chamber is in operation.

### DESCRIPTION OF DRAWINGS

FIG. 1 illustrates a simplified block diagram of a process chamber in which a set of wear compensating confinement ring is employed in accordance with the present invention.

FIG. 2 illustrates a vertical cross-sectional view of the wear compensating confinement ring in accordance with one implementation.

FIG. 3A illustrates an expanded view of a section of confinement ring with tapered slots of the present invention, in accordance with one implementation.

FIG. 3B illustrates an expanded view of the slot wear profile (i.e., starting and ending wear profiles) of the tapered slot of a wear compensating confinement ring of the present invention showing, in accordance with one implementation.

FIGS. 3C-3E illustrate graphical representations of amount of wear in the different sections along a length of the wear compensating confinement ring at different stages of usage life, in accordance with one implementation.

FIG. 4 is a top perspective view of the wear compensating confinement ring, in accordance with one implementation.

FIG. 5 is bottom perspective view of the wear compensating confinement ring, in accordance with one implementation.

FIG. 6 is a side view of the wear compensating confinement ring, in accordance with one implementation.

FIG. 7 is a top view of the wear compensating confinement ring, in accordance with one implementation.

FIG. 8 is a bottom view of the wear compensating confinement ring, in accordance with one implementation.

FIG. 9A is a magnified view of a portion of the bottom view of the wear compensating confinement ring of FIG. 8, in accordance with one implementation.

FIG. 9B is a magnified view of a tapered slot of the wear compensating confinement ring, in accordance with one implementation.

FIG. 10 is a magnified cross-sectional view of section 7-7 representing a cross-section between two tapered slot features of the wear compensating confinement ring of FIG. 7, in accordance with one implementation.

FIG. 11 is a magnified cross-sectional view of section 8-8 representing a cross-section of tapered slot feature of FIG. 7, in accordance with one implementation.

### DETAILED DESCRIPTION

Features of the confinement ring for use in a plasma processing chamber is described in the various implementations herein to improve the usage life of the confinement ring while continuing to improve plasma confinement. In some embodiments, the confinement ring includes using tapered slot geometry for the slots defined on the bottom section of the confinement ring. The tapered slot may result in some open area along the narrow side. To compensate for the open area along the narrow side, the total number of slots may be increased. An amount of increase in the number of slots takes into consideration the amount of wear anticipated along the inner diameter of the tapered slots. In some embodiments, the slots have a slot taper extending from a broader side at the outer diameter to the narrow side at the inner diameter. The broader side at the outer diameter has a broader outer slot radius and the narrow side at the inner diameter has a narrow inner slot radius. The inner slot radius at the inner diameter and the outer slot radius at the outer diameter defining the slot taper are sized to be an inverse of the wear rate at the corresponding inner diameter and the outer diameter. By sizing the slot taper to the inverse of the wear rate, an improvement in the usage life of the confinement ring is realized. At end of the usage life, the smaller inner slot radius at the inner diameter compensates for the high wear rate at the inner diameter resulting in a straight slot profile along the length of the slot. The difference in the inner slot radius and the outer slot radius results in each slot along the entire slot length to reach the confinement limit at the same time. Having a narrower slot at the inner diameter allows for more wear to occur before critical dimension for potential plasma leak is reached. Further, the tapered slot geometry reduces replacement frequency of the consumable confinement ring by extending the usage life (i.e., increase number of process cycles for which the confinement rings can be used).

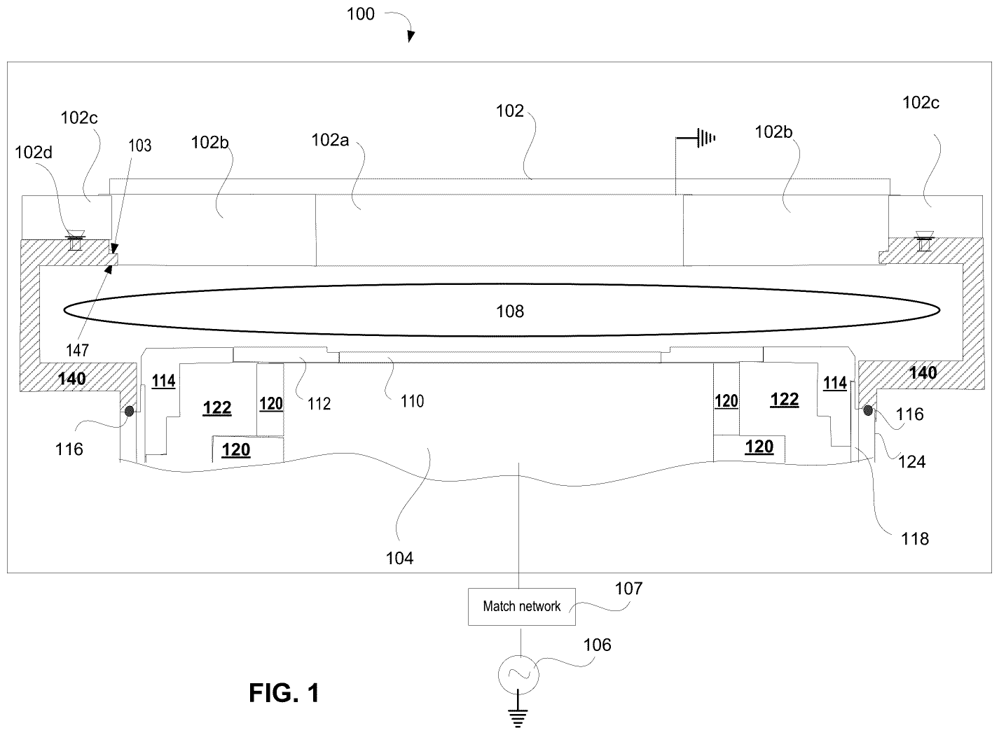

FIG. 1 illustrates a simplified block diagram of an example plasma processing chamber 100 in which a wear compensating confinement ring may be employed, in one implementation. The plasma processing chamber 100, in one implementation, may be a capacitively-coupled plasma (CCP) processing chamber (or simply referred to henceforth as a “plasma processing chamber”), which includes a lower electrode 104 to provide radio frequency (RF) power to the plasma processing chamber 100, and an upper electrode 102 to provide process gases to generate plasma within the plasma processing chamber 100. The lower electrode 104 may be connected to a RF power source 106 through a corresponding match network 107, wherein a first end of the RF power source 106 is connected to the match network 107 and a second end of the RF power source 106 is electrically grounded. The RF power source 106 may include one or more RF power generators (not shown).

In one implementation, the lower electrode 104 includes an electrostatic chuck (ESC) with a substrate support 110 defined at the top of the ESC to receive a substrate (not shown) for processing. The substrate support 110 is surrounded by an edge ring 112. A depth of the edge ring 112 is such that when the substrate is received over the substrate support 110, the top surface of the edge ring 112 is co-planar with a top surface of the substrate. The edge ring 112 is configured therefore to extend the processing region for the plasma from an edge of the substrate, when the substrate is received for processing, to an extended processing region (represented by the plasma region 108) defined to cover an outer edge of the edge ring 112. An outer confinement ring 114 is disposed adjacent to the outer edge of the edge ring 112. The outer confinement ring 114 may be used to further extend the extended plasma processing region 108 beyond the outer edge of the edge ring 112. In one implementation, a first (inner) portion of the edge ring 112 is disposed over the ESC, a second (mid) portion is disposed over a radio frequency (RF) conductive element 120, and a third (outer) portion is disposed over a quartz element 122 defined in the lower electrode 104. RF power source 106 is connected to a bottom portion of the ESC via the match network 107 and provides RF power to the process chamber 100. A ground ring 118 is disposed below a portion of an outer edge of the outer confinement ring 114 and is configured to surround the lower electrode 104. An outer ring 124 is disposed to surround a portion of the ground ring 118 of the lower electrode 104. A RF gasket 116 is disposed on a top surface of the outer ring 124. The outer ring 124 may be made of a quartz element or any other insulation material that is suitable for use in the plasma processing chamber 100.

In one implementation, the upper electrode 102 may be a showerhead that includes one or more inlets (not shown) connected to one or more process gas sources (not shown) and a plurality of outlets distributed at a bottom surface of the upper electrode 102 facing the lower electrode 104. The plurality of outlets are configured to supply the process gases from the one or more process gas sources to a plasma processing region (or simply referred to as “plasma region”) 108 defined between the upper electrode 102 and the lower electrode 104. The upper electrode 102 may be made up of a plurality of electrodes. FIG. 1 illustrates one such implementation in which the upper electrode 102 includes an inner electrode 102a disposed in the center, and an outer electrode 102b that is disposed adjacent to and surround the inner electrode 102a. The upper electrode 102, in this implementation, is electrically grounded to provide the RF power supplied to the plasma processing chamber 100 a return path to ground. The upper electrode 102 includes a showerhead extension 102c defined adjacent to an outer edge of the outer electrode 102b. The showerhead extension 102c includes a plurality of fastener means 102d that are used to couple the upper electrode 102 to a confinement ring structure 140.

A confinement ring structure (or simply referred to henceforth as “confinement ring”) 140 is disposed between the upper electrode 102 and the lower electrode 104. The confinement ring 140 defines a confined chamber volume in which the plasma generated in the chamber is sufficiently contained. The confinement chamber volume defines the plasma region 108. The confinement ring 140 is a C-shaped structure with an opening of the C-shape facing an inside of the plasma region 108 defined between the upper and the lower electrodes 102, 104, of the processing chamber 100. The confinement ring 140 is used to confine the plasma within an extended plasma region 108 in the plasma processing chamber 100. The confinement ring 140 is configured to be coupled at the top to the showerhead extension 102c of the showerhead 102, and at the bottom to the outer ring 124 of the lower electrode 104. The RF gasket 116 provided at the top surface of the outer ring 124 is configured to provide a coupling between the upper electrode 102 and the lower electrode 104. The confinement ring 140 is part of the upper electrode 102 and when the upper electrode 102 is lowered, a bottom extension of the confinement ring 140 rests on the outer ring and the RF gasket 116 ensures that the coupling between the upper and the lower electrodes is air-tight. In one implementation, the confinement ring 140 is positioned so that a gap exists between a bottom extension of the confinement ring 140 and the outer confinement ring 114 of the lower electrode 104.

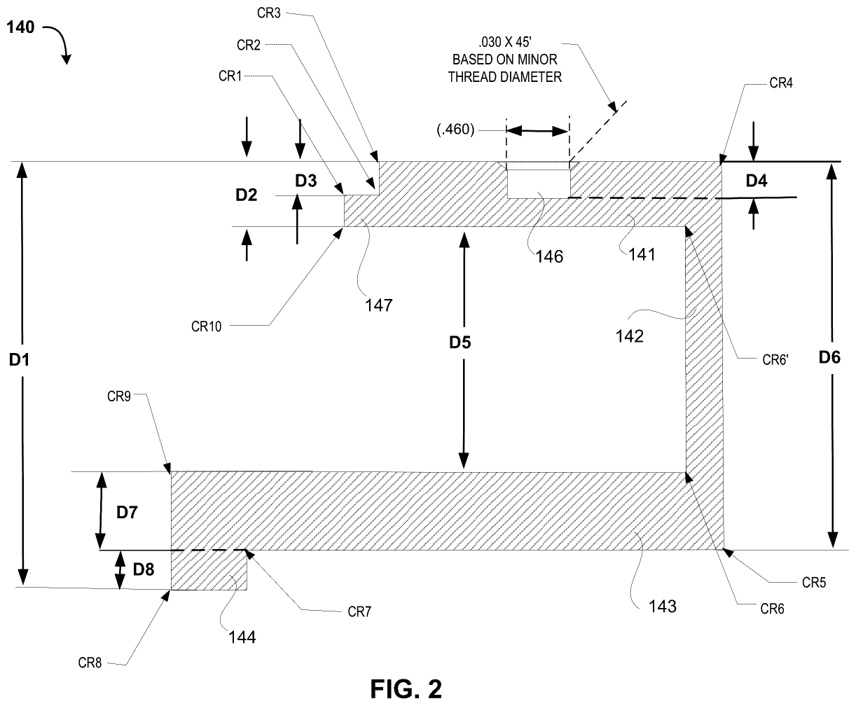

FIG. 2 illustrates an expanded cross-sectional view of the wear compensating confinement ring (otherwise referred to as “confinement ring”) 140 used in the plasma processing chamber, in one implementation. As noted, the confinement ring 140 is a C-shaped structure and includes an upper horizontal section 141, a vertical section 142, a lower horizontal section 143 and an extension section 144. The upper horizontal section 141 extends between an inner upper radius, ‘r1’ and an outer radius ‘r3’ of the confinement ring. The confinement ring 140 extends a height ‘D1’ from a top surface of the upper horizontal section and a bottom surface of the extension section 144. The upper horizontal section 141 extends for a height ‘D2’ (i.e., distance between a top surface to the bottom surface of the upper horizontal section 141). The upper horizontal section 141 includes a plurality of fastener holes (or simply referred to as “holes”) 146 defined on a top surface, wherein the fastener holes 146 are distributed uniformly in a circular orientation and defined to align with corresponding fastener means 102d disposed in the showerhead extension 102c of the upper electrode 102.

In one implementation, the fastener holes 146 extend for a depth ‘D4’ from a top surface of the upper horizontal section 141. In one implementation, a chamfer of about 0.03 mils×45 degree is added at the corner of the fastener holes 146. In this implementation, the chamfer is about 0.03 mils deep from the top surface and is about 0.03 mils on radius larger than the minor diameter of the thread (not shown). It is to be noted that the usage of the term “about” in defining the depth and radius dimensions of the chamfer may include a variation of +/−15%. In one implementation, the minor diameter is based on a screw thread standard implemented in the processing chamber 100. A step 147 is defined on the top surface of the upper horizontal section 141 proximate to the inner upper radius r1 and extends down and out toward the inner upper radius r1 of the confinement ring 140. In one implementation, the step 147 extends for a height ‘D3’ from the top surface of the upper horizontal section 141. A portion of a bottom surface of the outer electrode 102b includes a complementary extension 103 to mate with the step 147 defined in the upper horizontal section 141 of the confinement ring 140. The step 147 and the complementary extension 103 may be provided to offer reliable mating of the confinement ring 140 to the upper electrode 102.

The vertical section 142 is defined at the outer radius r3 of the confinement ring 140 and is configured to integrally continue the lower horizontal section 143 to the upper horizontal section 141. The vertical section 142 extends to a height ‘D5’ defined to cover the plasma region 108 defined in the plasma processing chamber 100. Consequently, the height D5 of the vertical section 142 is defined to be equal to a separation distance between a bottom surface of the upper electrode 102 and the top surface of the lower electrode 104.

The lower horizontal section 143 extends between an inner lower radius ‘r2’ and the outer radius r3 of the confinement ring 140. In one implementation, the inner lower radius r2 of the confinement ring 140 is smaller than the inner upper radius r1 of the confinement ring 140. In one implementation, the lower horizontal section 143, excluding the extension section 144, extends for a depth ‘D7’ (i.e., distance between a top surface and a bottom surface of the lower horizontal section 143 excluding the extension section 144). In one implementation, the confinement ring 140 extends for a height ‘D6’ from the top surface of the upper horizontal section 141 and the bottom surface of the lower horizontal section 143 excluding the extension section 144. The lower horizontal section 143 includes the extension section 144 defined at the inner lower radius r2. The extension section 144 extends vertically down from the inner lower radius r2 of the lower horizontal section 143 and provides an integral continuity to the lower horizontal section 143. The extension section 144 extends for a height ‘D8’ from a bottom surface of the lower horizontal section 143 and is configured to rest on the RF gasket 116 that is defined on the top surface of the outer ring 124 defined in the lower electrode 104. The outer ring 124 of the lower electrode 104 is configured to surround a region of the lower electrode 104 that includes at least the ESC, the substrate support 110, the edge ring 112, the outer confinement ring 114, the ground ring 118, the RF conductive element 120, and the quartz elements 122. When the upper electrode 102 is lowered, the RF gasket 116 provides a tight coupling between the lower electrode 104 and the upper electrode 102.

In one implementation, a height ‘D1’ of the confinement ring 140 from a top surface of the upper horizontal section 141 to a bottom surface of the extension section 144 is defined to be between about 1.5 inches and about 2.75 inches. In one example implementation, the height D1 is about 2.4 inches. In another example implementation, the height D1 is about 2.4 inches. In one implementation, a height ‘D2’ of the upper horizontal section 141 is defined to be between about 250 mils (thousandth of an inch) and about 400 mils. In one example implementation, the height D2 is about 310 mils. In one implementation, the height ‘D3’ of the step 147 is defined to be between about 150 mils and about 180 mils. In one example implementation, the height D3 is about 165 mils. In one implementation, the fastener hole 146 extends to a depth ‘D4’ of between about 200 mils and about 300 mils. In one example implementation, the height D4 is about 200 mils. In one implementation, the height ‘D5’ of the vertical section 142 is defined to be between about 0.75 inches and about 2.35 inches. In one example implementation, the height D5 is about 1.6 inches. In another example implementation, the height D5 is about 1.6 inches. In one implementation, the height ‘D6’ of the confinement ring 140 from a top surface of the upper horizontal section 141 and the bottom surface of the lower horizontal section 143 and excluding the extension section 144 is defined to be between about 1.25 inches and about 2.5 inches. In one example implementation, the height D6 is defined to be about 2.2 inches. In one implementation, a depth ‘D7’ of the lower horizontal section 143 excluding the extension section 144 is defined to be between about 300 mils and about 600 mils. In one example implementation, the height D7 is defined to be about 490 mils. In one implementation, the height ‘D8’ of the extension section 144 is defined to be between about 100 mils and about 400 mils. In one example implementation, the height D8 is defined to be about 200 mils. It is to be noted that the usage of the term “about” in defining the height and depth dimensions of the various components of the confinement ring 140 described herein may include a variation of +/−15% of the associated value.

Of course, the dimensions provided for the various components of the confinement ring 140 are provided as a mere example and should not be considered limiting or exhaustive. Variations in the dimensions can be envisioned based on the inner dimensions of the plasma processing chamber 100, the type of process that is being performed, the type of process gases being used to generate the plasma, the type of by-products and neutral gas species that are generated and need to be removed, etc. In one implementation, the confinement ring is made of silicon. In other implementations, the confinement ring may be made of polysilicon, or silicon carbide, or boron carbide, or ceramic, or aluminum, or any other material that can withstand the processing conditions of the plasma region 108.

In one implementation, the various corners of the confinement ring 140, including the inner and the outer corners, are configured to be rounded. In one implementation, the various corners are rounded to preserve the integrity of the confinement ring structure 140 and to prevent deposition of particulate matters included in the by-products generated by the plasma. Further, the corners may be rounded to prevent chipping. FIG. 2 illustrates the different rounded corners that can be envisioned in the confinement ring 140, in one implementation. The rounded corners are defined by curvature radius. In one implementation, each rounded corner has a different curvature radius. In an alternate implementation, all the rounded corners may have the same curvature radius. In yet another implementation, some of the rounded corners may have same curvature radius while other corners may have different curvature radius. The curvature radius defined for different corners may be based on the level of exposure the respective corners may have to the plasma and, in some instances, the geometry of the surrounding surfaces of the plasma processing chamber 100.

FIG. 2 illustrates example dimensions of the curvature radius for the different corners of the confinement ring 140, in one implementation. In this implementation, the curvature radius CR1 at the upper outer corner of the step 147 may be between about 10 mils and about 40 mils. In one example implementation, the curvature radius CR1 is about 25 mils. The curvature radius CR2 at the inner corner of the step 147 is defined to be between about 5 mils and about 40 mils. In one example implementation, the curvature radius CR2 is defined to be about 25 mils. The curvature radius CR3 at the top inner corner of the top surface of the upper horizontal section 141 may be between about 10 mils and about 40 mils. In one example implementation, the curvature radius CR3 is about 25 mils. The curvature radius CR4 at the top outer corner of the upper horizontal section 141 is between about 10 mils and about 40 mils. In one example implementation, the curvature radius CR4 is about 25 mils. The curvature radius CR5 at the bottom outer corner of the lower horizontal section 143 is between about 10 mils and about 40 mils. In one example implementation, the curvature radius CR5 is about 25 mils.

The curvature radius CR6 at the top inner corner of the lower horizontal section 143 is defined to be between about 50 mils and about 250 mils. In one example implementation, the curvature radius CR6 is about 150 mils. The dimensions of the inner corner CR6′ along a bottom surface of the upper horizontal section 141 may be defined to be similar to the curvature radius CR6. The curvature radius CR7 at the inner bottom corner between the lower horizontal section 143 and the extension section 144 is defined to be between about 10 mils and about 40 mils. In one example implementation, the curvature radius CR7 is about 25 mils. The curvature radius CR8 at the bottom outer corner of the extension section 144 is defined to be between about 10 mils and about 40 mils. In one example implementation, the curvature radius CR8 is about 25 mils. The curvature radius CR9 at the top outer corner of the lower horizontal section 143 is defined to be between about 10 mils and about 125 mils. In one example implementation, the curvature radius CR9 is defined to be about 25 mils. The curvature radius CR10 at the bottom outer corner of the upper horizontal section 141 is defined to be between about 10 mils and about 40 mils. In one example implementation, the curvature radius CR10 is about 30 mils. It is to be noted that the usage of the term “about” in defining the curvature radius dimensions of the various corners of the confinement ring 140 described herein may include a variation of +/−15% of the associated value.

Of course, the aforementioned dimensions for the various curvature radii of the confinement ring 140 are provided as an example and should not be considered restrictive or exhaustive. Other curvature radii dimensions can also be envisioned depending on the geometry of the confinement ring 140, the geometry of the other components of the plasma processing chamber 100 surrounding the confinement ring 140, the level of exposure the various corners to the plasma, and the amount of effect the by-products have on the different corners of the confinement ring 140. In one implementation, a width of the fastener hole 146 defined on the top surface of the upper horizontal section 141 may be defined to be between about 35 mils to about 60 mils. In one implementation, the fastener hole may include a top outer diameter of about 30 mils×45′ to accommodate minor thread diameter.

The lower horizontal section 143 includes a plurality of slots 145, wherein each slot 145 extends radially between an inner diameter ‘ID1’ and an outer diameter ‘OD1’. The inner diameter ID1 of the slot 145 defined in the lower horizontal section 143 is greater than an inner ring diameter IRD1 (defined by the inner lower radius r2) of the confinement ring 140. The outer diameter OD1 of the slot 145 defined in the lower horizontal section 143 is greater than the inner diameter ID1 of the slot 145 but less than the outer ring diameter ‘ORD1’ of the confinement ring 140. The slots 145 are defined for a length ‘l2’ (i.e., l2=OD1−ID1) that is less than the width ‘l1’ (i.e., l1=ORD1-IRD1) of the lower horizontal section 143. Further, each of the slots 145 is defined using tapered slot geometry to include a slot taper. The slot taper is formed by defining a narrow inner slot radius ‘ISR’ at the inner diameter ID1 of the slot 145 and a broader outer slot radius ‘OSR’ at the outer diameter OD1 of the slot 145. To compensate for narrow inner slot radius ISR at the inner diameter ID1, in one implementation, the length l2 of the slot 145 is increased so as to provide sufficient slot area for removing the by-products and neutral gas species.

The variation in the outer slot radius OSR and the inner slot radius ISR results in each slot being narrower at the inner diameter ID1 (145a) and wider at the outer diameter OD1 (145b). The inner slot radius ISR and the outer slot radius OSR of each slot 145 are sized to be an inverse of a wear rate at the corresponding inner and outer diameters (ID1, OD1) of the slot 145. Further, the size of the inner slot radius ISR and the outer slot radius OSR are defined to enable removal of the by-products and the neutral gas species from the plasma region 108. This variation in the radius allows the slot wear profile at the inner diameter ID1 to reach a critical dimension limit at about the same time as the slot wear profile at the outer diameter OD1 of the slot 145, thereby extending usage life of the confinement ring 140.

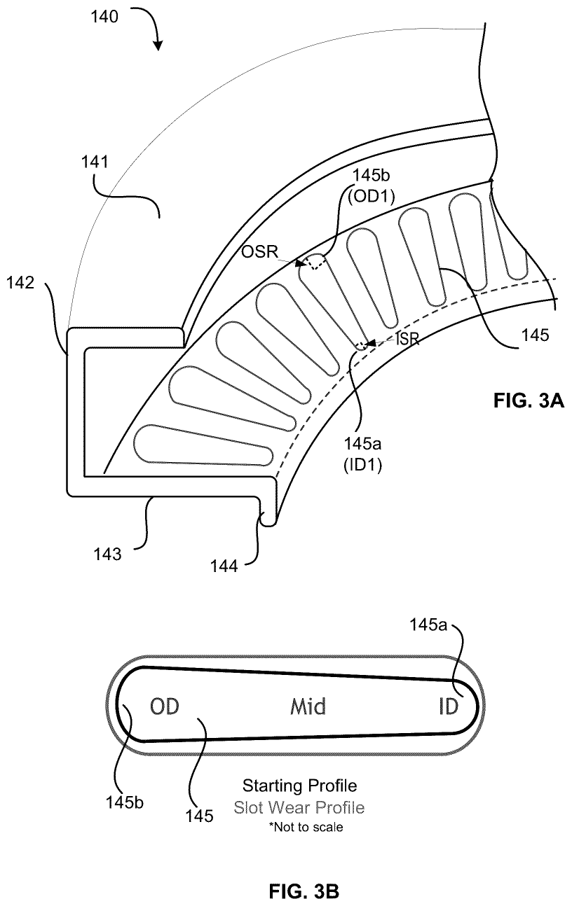

FIG. 3A illustrates a magnified view of a portion of the confinement ring 140 showing a tapered slot profile of the slots 145 of the current invention, in accordance with one implementation. The slots 145 illustrated in FIG. 3 are not to scale, but have been exaggerated to illustrate how the inner slot radius ISR is smaller than the outer slot radius OSR at the beginning of the usage life of the confinement ring in the plasma processing chamber 100 (i.e., prior to the confinement ring being exposed to the plasma process). Accordingly, each of the plurality of slots 145 includes a slot taper defined by a wider outer slot radius OSR at the outer diameter OD1 (145b) and a narrower inner slot radius ISR at the inner diameter ID1 (145a). The variation in the outer slot radius OSR and the inner slot radius ISR results in each slot 145 being narrower at the inner diameter ID1 (145a) and wider at the outer diameter OD1 (145b). The inner slot radius ISR and the outer slot radius OSR of each slot are sized to be an inverse of wear rate at the corresponding inner and outer diameters (ID1, OD1) of the slot 145 defined in the lower horizontal section 143. Further, the size of the inner slot radius ISR and the outer slot radius OSR are defined to ensure that the by-products and the neutral gas species can escape the plasma region 108, while confining the plasma in the plasma region 108. The variation in the slot radius allows the slot wear at the inner diameter ID1 to reach a critical dimension at about the same time as the slot wear at the outer diameter OD1, thereby improving usage life of the confinement ring 140.

FIG. 3B illustrates the wear profile of the tapered slot 145 of the current invention, in one implementation. The initial slot profile of the tapered slots 145 defined in the confinement ring 140 is shown in black line while the wear profile to which the tapered slot 145 can wear before reaching the critical dimension limit, is shown in red line. The narrow slot profile at the inner diameter ID1 provides additional wear area than the broader slot profile at the outer diameter OD1 so as to allow the confinement ring 140 to undergo additional process operations within the plasma processing chamber before the wear profile of the confinement ring 140 reaches the critical dimension limit and the confinement ring 140 has to be replaced.

The increase in the usage life of the confinement ring 140 can be attributed to the fact that additional wear area is provided at the inner diameter ID1 (145a) than at the outer diameter OD1 (145b). As the wear at the inner diameter ID1 is more than at the outer diameter OD1, providing tapered slot profile allows the confinement ring to undergo more process operations and use the additional wear area at the narrow end before the narrow end reaches the critical dimension limit for plasma unconfinement. Further, as the wear at the broader end of the slot is less, the outer diameter reaches the critical dimension limit slower than the narrow end and can therefore withstand the same amount of process operations as the narrow end before the broad end of the slot reaches the critical dimension limit.

The slot taper, defined by the wider slot dimension at the outer diameter OD1 and the narrow slot dimension at the inner diameter ID1, is sized to be an inverse of the wear rate. By sizing the slot taper as a function of the wear rate, the high wear rate at the inner diameter ID1 is compensated for by the low wear rate at the outer diameter OD1, thereby resulting in an approximate straight slot profile at end of life. The slot width along the entire slot length reaches the confinement limit (i.e., critical dimension) at about the same time. The tapered geometry makes use of the area at the outer diameter more effectively. To compensate for the open areas in the lower horizontal section due to decrease in the dimension of the slot at the inner diameter, additional slots may be defined. The number of additional slots may be defined by taking into consideration the amount of wear space required at the narrow end and the broad end for each slot to reach the critical dimension. The tapered slot geometry extends the amount of wear the slot can tolerate before reaching the unconfinement limit, resulting in longer usage life and improved cost of consumables.

FIGS. 3C-3E illustrate graphical representations of the extent to which the wear profile varies at different portions of the tapered slot 145 of the present invention during different stages of usage life of the confinement ring 140, in one implementation. The graphs are plotted with exposure time vs. slot width. The starting slot width for wear is depicted by line 305, in one implementation, at the beginning of the usage life of the confinement ring (i.e., at a time when the confinement ring has not been exposed to any plasma). Due to the tapered slot geometry of the confinement ring 140, the line 305 represents the beginning slot width of the slot 145 and the positions of the initial slot widths of the corresponding portions along the length of the slot 145 in relation to line 305. The critical dimension limit (i.e., ending slot width reaching the wear limit) for the different portions of the tapered slot is represented by line 306. Line 306 represents the critical dimension limit for slot wear at the different portions of the slot 145 before reaching the potential plasma unconfinement stage.

FIG. 3C illustrates the starting stage of the usage life of the confinement ring 140 according to some implementations, when the confinement ring 140 has been newly installed, for example, and no process cycles have been performed (i.e., exposure time t₀). The graph shows various sections of the slots represented as dots in different colors, wherein the different colored dots include the blue dots representing the outer diameter OD1 section of the slot 145, the green dots representing the mid-section of the slot 145, and the red dots representing the inner diameter ID1 section of the slot 145. At the start of the usage life, the dots from each section of the slot 145 are shown to be at their respective starting slot widths in relation to line 305, with the red dots corresponding to the inner diameter ID1 being proximal to the line 305, the blue dots corresponding to the outer diameter OD1 shown at a distance relative to line 305, and the green dots corresponding to the mid-section shown in-between the red dots and the blue dots. As can be understood, the amount of area for slot wear at the inner diameter ID1 is greater than the amount of area available for slot wear at the outer diameter OD1.

The extra area available at the inner diameter ID1 due to the narrow inner slot radius allows for more slot wear to occur at the inner diameter ID1 before the slot wear at the inner diameter ID1 reaches the critical dimension limit. Similarly, the smaller area available at the outer diameter OD1 due to the broader outer slot radius allows for less slot wear at the outer diameter OD1 before the slot wear at the outer diameter reaches the critical dimension limit. This is illustrated in FIG. 3C with the red dots of the section at the inner diameter ID1 shown to be located proximal to line 305, the blue dots of the section at the outer diameter OD1 shown to be located at some distance from line 305, wherein the distance from line 305 corresponds to the difference between the outer slot radius and the inner slot radius representing the slot taper, and the green dots of the mid-section shown to be located between the red dots and the blue dots. Further, FIG. 3C shows example slopes of projected slot wear for the different sections of the confinement ring, wherein the red line slope corresponds to the slot wear at the inner diameter ID1, the blue line slope corresponds to the slot wear at the outer diameter OD1 and the green line slope corresponds to the slot wear at the mid-section of the slot 145. The slopes are provided to illustrate the rate at which the different portions of the slot 145 wears as the different portions of the slot 145 are exposed to a number of process cycles.

FIG. 3D illustrates a graphical representation of the wear profile of the slot wear of each slot 145 after ‘m’ process cycles have been completed in the plasma processing chamber according to some implementations, where m is an integer. The dots from the different portions are shown to have moved from the initial slot width represented in FIG. 3C to the corresponding positions illustrated in FIG. 3D along the respective slopes of the slot wear. The slot wear at the inner diameter ID1 is shown to have a steeper incline as shown by the red line slope to indicate that the slot wear at the inner diameter ID1 is more. Similarly, the slot wear at the outer diameter OD1 is shown to have a gentle incline as shown by the blue line slope to indicate that the slot wear at the outer diameter OD1 is less, and the slot wear at the mid-section is shown to have an incline that is in-between the green line slope and the red line slope. The inclines of the slopes are shown to indicate that the slot wear of the slot 145 steadily increases as the slot is exposed to increasing number of process cycles.

FIG. 3E illustrates a graphical representation of the wear profile of the slot wear at each slot 145 after ‘n’ process cycles according to some implementations, where n is an integer that is greater than m. The graph shows the slot wear at the inner diameter ID1 represented by the red dots approaching the line 306, representing critical dimensional limit, at about the same time as the portions of the slot 145 represented by green and blue dots. Consequently, the line 306 may represent the end of the usage life of the confinement ring 140 — i.e., the stage where there is high likelihood of plasma unconfinement event occurring and when the confinement ring is to be replaced. As can be seen from FIGS. 3C-3E, the wear at the different portions along the length of the slot 145 approaches the critical dimension limit at about the same time with the narrow end of the slot 145 having more area for wear and the broader end having less area for wear. Due to the tapered geometry of the slot 145, the slot wear area around the outer diameter OD1 is used effectively while the extra area provided at the inner diameter ID1 allows the confinement ring to endure more wear before the confinement ring 140 has to be replaced. The tapered slot geometry thus extends the usage life of the confinement ring by allowing the confinement ring to undergo more process cycles before having to be replaced.

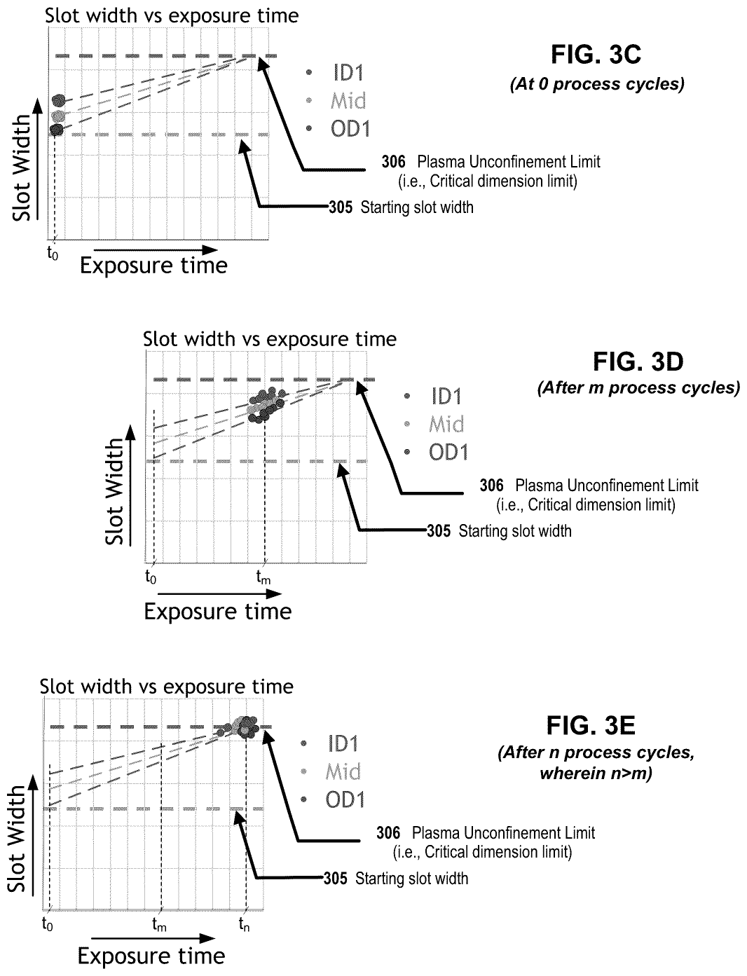

FIG. 4 illustrates a top perspective view of the confinement ring 140 used in the plasma processing chamber 100 to confine the plasma in the plasma region 108. The confinement ring 140 is a C-shaped structure that is configured to be disposed along a periphery of the plasma region 108 to confine the plasma in the plasma region 108 that extends over a substrate support 110, edge ring 112 and an outer confinement ring 114. The confinement ring 140 is a replaceable consumable part. A top surface of the confinement ring includes a plurality of fastener holes 146 disposed uniformly in a circular orientation, wherein the fastener holes 146 are configured to align with and receive fastener means 102d defined in a showerhead extension 102c of the upper electrode 102.

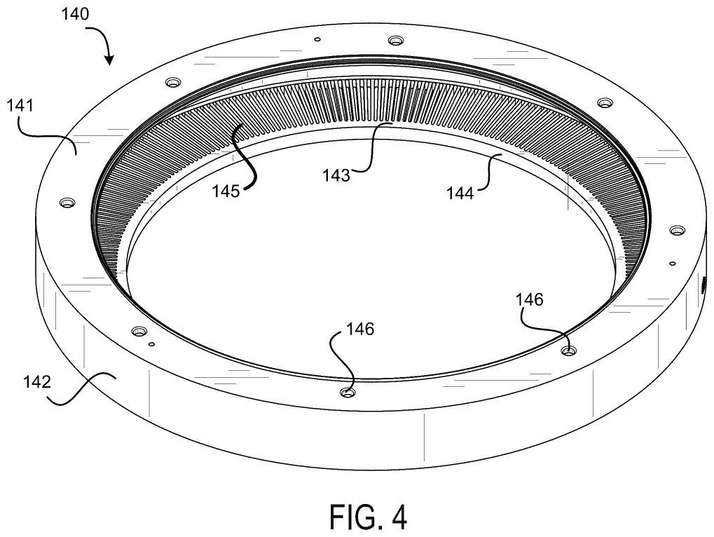

FIG. 5 illustrates a bottom perspective view of the confinement ring 140 used in the plasma processing chamber 100 to confine the plasma in the plasma region 108. The bottom view shows the plurality of slots 145 with tapered profile defined along the lower horizontal section 143. Number and size of the slots 145 in the lower horizontal section 143 is defined to allow optimal removal of the by-products and neutral gas species from the plasma region 108.

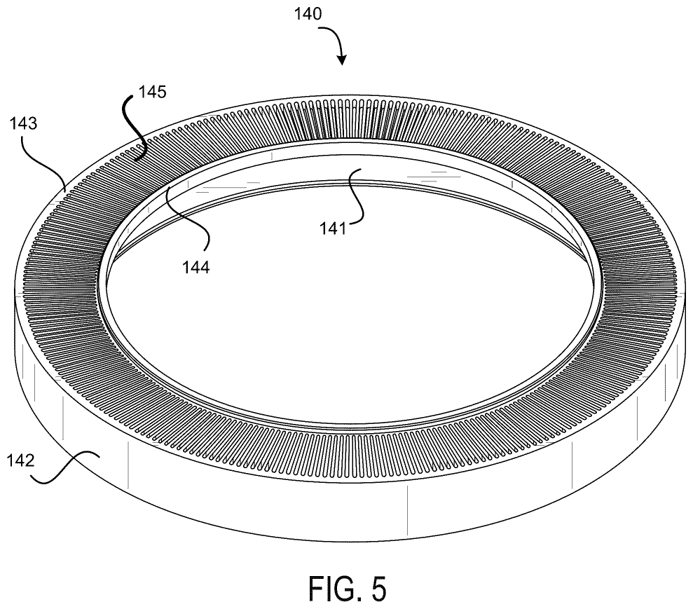

FIG. 6 illustrates a side view of the confinement ring 140. The side view shows the vertical section 142 that extends between the upper horizontal section 141 and the lower horizontal section 143. The side view also shows the extension section 144 that extends vertically down from the inner lower radius r2 of the confinement ring 140.

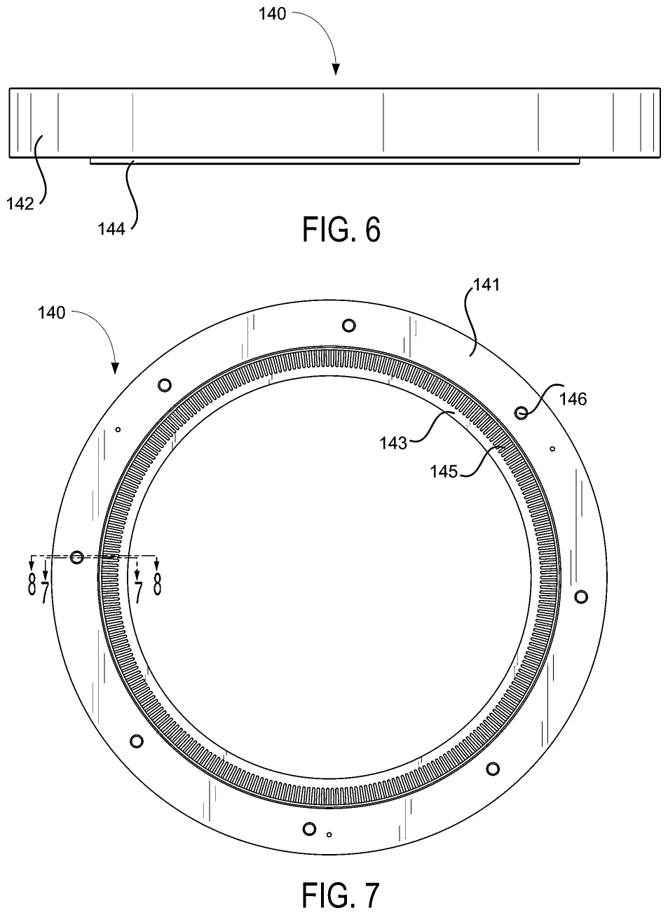

FIG. 7 illustrates a top view of the confinement ring 140 used in the plasma processing chamber. The confinement ring 140 is disposed between the upper electrode 102 and the lower electrode 104 and is C-shaped in structure. The C-shaped structure confines the plasma in the plasma region 108, which extends to cover the region over the substrate support 110, edge ring 112, and the outer confinement ring 114. A plurality of fastener holes 146 defined on the top surface of the upper horizontal section 141 are configured to receive fastener means 102d defined on the underside surface of the showerhead extension 102c of the upper electrode 102.

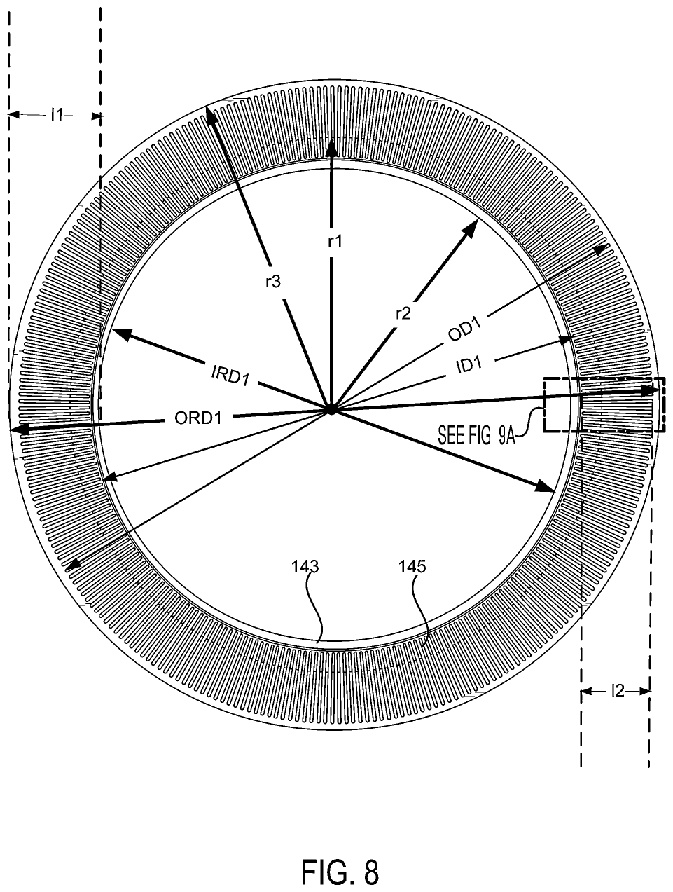

FIG. 8 is a bottom view of the confinement ring 140 used in the plasma processing chamber 100 and shows details of the bottom surface of the confinement ring 140. The bottom surface of the confinement ring 140 includes a plurality of slots with tapered geometry distributed along the lower horizontal section 143. The slots extend between the top surface and the bottom surface of the lower horizontal section 143 of the confinement ring 140 to provide a path for removing the by-products and neutral gas species from the confined volume of the process region 108. The slots 145 extend radially between an inner diameter ID1 and the outer diameter OD1. The lower horizontal section 143 has a width ‘l1’ and each slot 145 has a length ‘l2’ that is less than the width l1 of the lower horizontal section 143, wherein the width l1 of the lower horizontal section 143 extends between the inner lower radius r2 (i.e., used to define the inner ring diameter IRD1) and the outer radius r3 (i.e., used to define the outer ring diameter ORD1) of the confinement ring 140. Further, the inner diameter ID1 of the slot 145 defined in the lower horizontal section 143 is greater than the inner ring diameter IRD1 of the confinement ring 140. The outer diameter OD1 of the slot 145 in the lower horizontal section 143 is greater than the inner diameter ID1 of the slot 145 and the inner ring diameter IRD1 of the confinement ring 140, but is smaller than the outer ring diameter ORD1 of the confinement ring 140. The width l1 of the lower horizontal section 143 is greater than the width of the upper horizontal section 141, wherein the width of the upper horizontal section 141 extends between the inner upper radius r1 and the outer radius r3 of the confinement ring 140.

In one implementation, the width l1 of the lower horizontal section 143 is defined to be between about 2.25 inches and about 4.75 inches. In one example implementation, the width l1 of the lower horizontal section 143 is about 2.81 inches. In one implementation, the radial length l2 of the slot 145 is defined to be between about 1.85 inches and about 4.35 inches. In one example implementation, the radial length l2 of the slot 145 is defined to be about 2.2 inches. In one implementation, the inner upper radius r1 of the upper horizontal section 141 of the confinement ring 140 is defined to be between about 8.25 inches and about 9.0 inches. In one example implementation, the inner upper radius r1 of the upper horizontal section 141 of the confinement ring 140 is defined to be about 8.4 inches. In one implementation, the inner lower radius r2 of the confinement ring 140 is defined to be between about 7.25 inches and about 8.5 inches. In one example implementation, the inner lower radius r2 of the lower horizontal section 143 of the confinement ring 140 is defined to be about 7.44 inches. In one implementation, the inner ring diameter IRD1 (i.e., 2×inner lower radius r2) of the confinement ring 140 is defined to be between about 14.5 inches and about 17.0 inches. In one example implementation, the inner ring diameter IRD1 is defined to be about 14.9 inches. In one implementation, the outer radius r3 of the confinement ring 140 is defined to be between about 8 inches and about 12 inches. In one example implementation, the outer radius r3 of the confinement ring 140 is defined to be about 10.25 inches. In one implementation, the outer ring diameter ORD1 (i.e., 2×outer radius r3) of the confinement ring 140 is defined to be between about 16.0 inches and about 24.0 inches. In one example implementation, the outer ring diameter ORD1 is defined to be about 20.5 inches.

In one implementation, the inner slot radius ISR at the narrow end of the slot 145 is defined to be between about 0.02 inches and about 0.06 inches. In one example implementation, the ISR of the slot 145 is defined to be about 0.04 inches. In one implementation, the outer slot radius OSR at the broader end of the slot 145 is defined to be between about 0.03 inches and about 0.09 inches. In one example implementation, the OSR at the broader end of the slot 145 is defined to be about 0.046 inches. In some implementations, the OSR may be about 10%, 15%, 20%, 25%, 30%, 35%, 40%, 45% or 50% greater than the ISR. In some implementations, the OSR is about 20% greater than the ISR. In one implementation, the inner diameter ID1 of the slot 145 defined in the lower horizontal section 143 of the confinement ring 140 is defined to be between about 15 inches and about 16.75 inches. In one example implementation, the inner diameter ID1 is about 15.4 inches. In one implementation, the outer diameter OD1 of the slot 145 defined in the lower horizontal section 143 of the confinement ring 140 is defined to be between about 18.6 inches and about 23.6 inches. In one example implementation, the outer diameter OD1 is about 20.0 inches. In another example implementation, the outer diameter OD1 is about 19.95 inches. Of course, the aforementioned dimensions for the various components of the confinement ring 140 is provided as an example and may vary depending on the geometry of the plasma processing chamber, the plasma process performed in the chamber, the separation distance between the upper electrode and the lower electrode, etc. Further, it is to be noted that the usage of the term “about” in defining the various diameters and radii of the different sections of the confinement ring described herein may include a variation of +/−15% of the associated value.

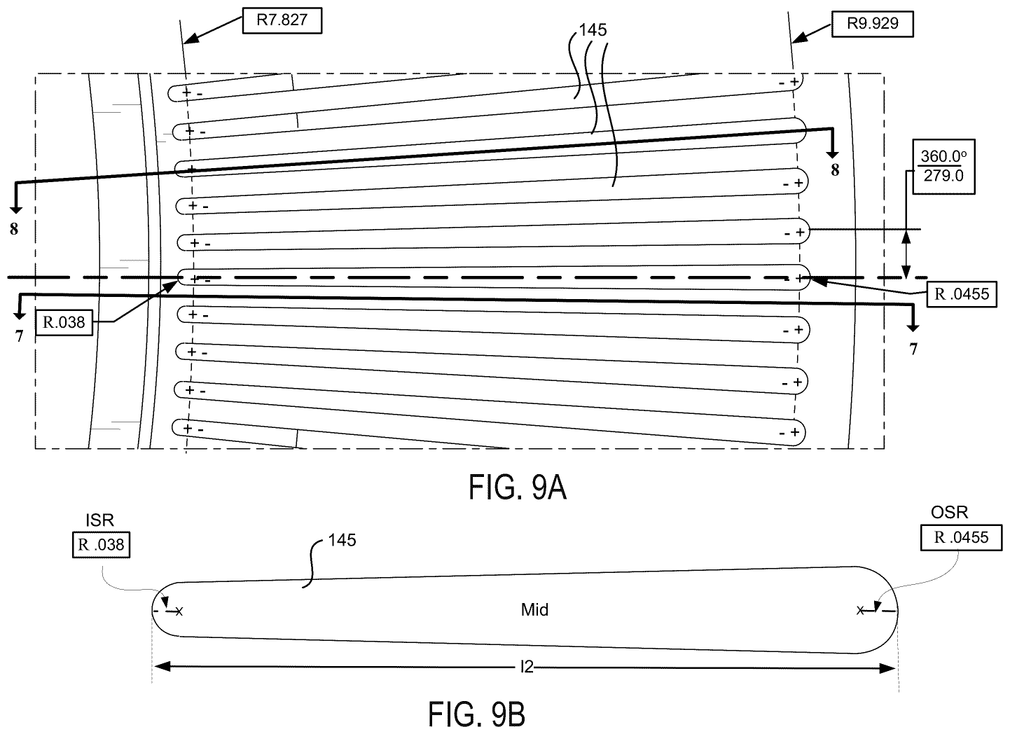

FIG. 9A illustrates an expanded view of a portion of a bottom surface of the lower horizontal section 143 of the confinement ring 140 with a plurality of slots 145 with tapered geometry of the current invention defined thereon. The tapered profile of each slot 145 includes a narrower inner slot radius ISR at an inner diameter ID1 145a and broader outer slot radius OSR at an outer diameter OD1 145b. In one implementation, the ratio of the inner slot radius ISR to the outer slot radius OSR of the slot 145 is defined to be between about 1:1.1 and about 1:1.5. In one implementation, an angle of separation between any pair of adjacent slots 145 is defined to be between about 360°/270° and about 360°/285°. In one example implementation, the angle of separation between any pair of adjacent slots 145 is defined to be about 360°/279°.

FIG. 9B illustrates an expanded view of a slot 145 with the tapered profile of the current invention. The ends of the slot 145 have a rounded profile. The rounded profile ends of the slot 145 show a narrower inner slot radius ISR at the inner diameter ID1 145a and a broader outer slot radius OSR at the outer diameter OD1 145b of the slot 145. Difference in the inner slot radius ISR and the outer slot radius OSR defines a slot taper for each slot 145. The slot taper is defined as an inverse of the wear rate at the inner and the outer diameters (ID1, OD1) of the lower horizontal section 143 of the confinement ring 140. In one example implementation illustrated in FIG. 9B, the ratio of the inner slot radius ISR to the outer slot radius OSR is shown to be about 1:1.2. The ratio provided in FIG. 9B is just one example and that other ratio can also be envisioned.

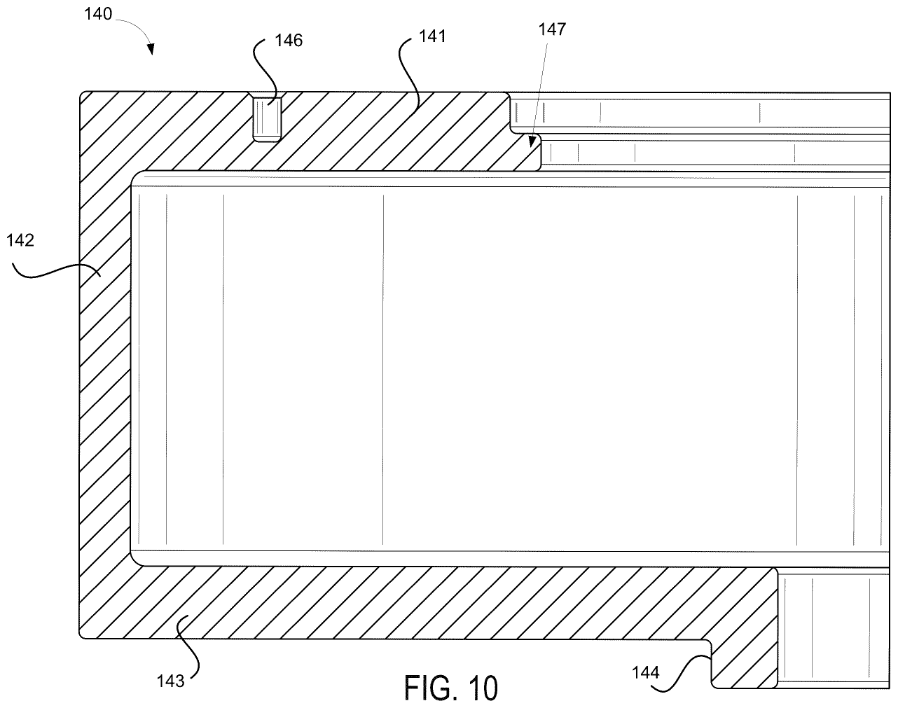

FIG. 10 illustrates a cross-sectional view of a section 7-7 of the confinement ring 140 illustrated in FIG. 9A. The cross-sectional view of section 7-7 of the confinement ring 140 is a view of a section of the confinement ring 140 between two tapered slots 145. The cross-sectional view of section 7-7 of the confinement ring 140 shows the upper horizontal section 141, the vertical section 142, the lower horizontal section 143, and the extension section 144 defined vertically down from the lower horizontal section 143 at the inner lower radius. The inner radius of the upper horizontal section 141 includes the step 147 that is configured to receive a complementary extension 103 of an outer electrode 102b. The extension section 144 is shown to extend vertically down from the inner lower radius of the lower horizontal section 143. A fastener hole 146 is defined at the top surface of the upper horizontal section 141.

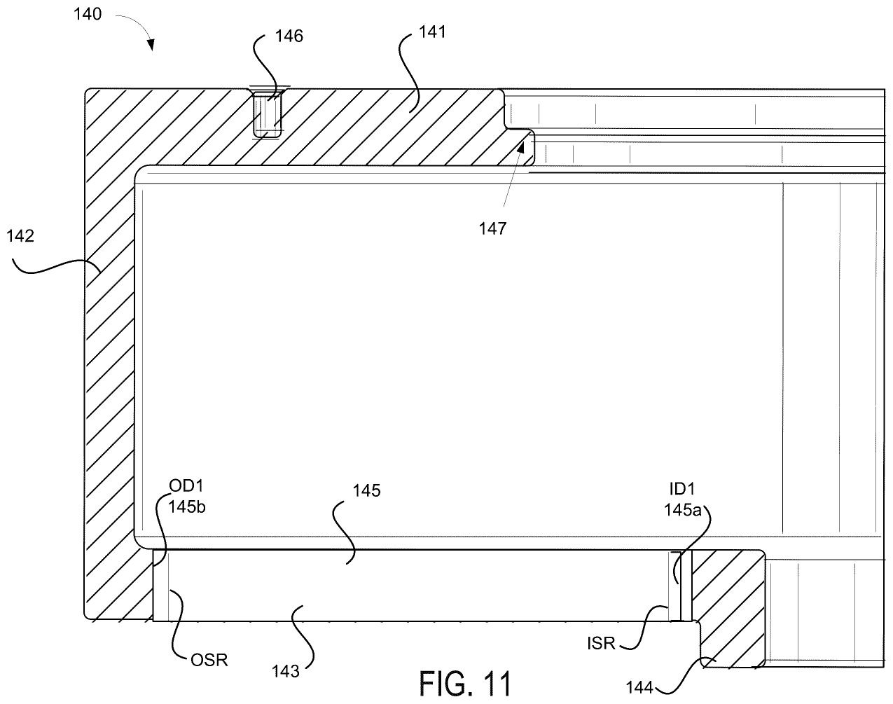

FIG. 11 illustrates a cross-sectional view of a section 8-8 of the confinement ring 140 illustrated in FIG. 9A. The cross-sectional view of the section 8-8 of the confinement ring 140 is a view of a section of the confinement ring 140 where a slot 145 is defined. A fastener hole 146 at the top surface of the upper horizontal section 141 is defined to receive fastener means included in the showerhead extension 120c (not shown). The lower horizontal section 143 shows a slot 145 which includes a tapered profile that tapers down from the outer diameter OD1 145b to the inner diameter ID1 145a. The tapered slots 145 are defined by the outer slot radius OSR defined at the outer diameter OD1 (145b) and the inner slot radius ISR at the inner diameter ID1 (145a).

The various implementations discussed herein of using a tapered slot geometry to define slots in the lower horizontal section of the confinement ring 140 is shown to improve the usage life of the confinement ring 140 while maintaining efficient plasma confinement within the plasma region 108. Consequently, the cost associated with the consumable confinement ring is lowered as the number of process cycles the confinement ring can be used in the plasma processing chamber is extended. The tapered slot geometry allows the area at the outer diameter to be more effectively used. This results in the slot width along the entire length to more or less reach the critical confinement dimension at end of life. The tapered slot extends the amount of wear the slot can tolerate before reaching the unconfinement limit, resulting in a longer lifetime and improved cost of consumables.

1. A confinement ring, including,
a lower horizontal section extending between an inner lower radius and an outer radius of the confinement ring, the lower horizontal section includes an extension section that extends vertically downward at the inner lower radius, and the lower horizontal section further includes a plurality of slots, wherein each slot extends radially from an inner diameter to an outer diameter along the lower horizontal section, an inner slot radius of each slot at the inner diameter is less than an outer slot radius of each slot at the outer diameter;
an upper horizontal section extending between an inner upper radius and the outer radius of the confinement ring; and
a vertical section that integrally continues the lower horizontal section to the upper horizontal section at the outer radius of the confinement ring.

2. The confinement ring of claim 1, wherein a difference in the inner slot radius and the outer slot radius of each slot defines a slot taper, such that each slot tapers down from the outer diameter to the inner diameter, wherein the inner slot radius and the outer slot radius influencing the slot taper are sized to be an inverse of a wear rate at the corresponding inner diameter and the outer diameter of the slot.

3. The confinement ring of claim 1, wherein the inner upper radius is greater than the inner lower radius.

4. The confinement ring of claim 1, wherein a step is defined on a top surface of the upper horizontal extension proximal to the inner upper radius, the step extending down from the top surface and out toward the inner upper radius of the confinement ring.

5. The confinement ring of claim 1, wherein the inner diameter is greater than an inner ring diameter defined by the inner lower radius and the outer diameter is less than an outer ring diameter defined by the outer radius of the confinement ring.

6. The confinement ring of claim 1, wherein a length of each slot is defined to be between about 1.85 inches and about 4.35 inches.

7. The confinement ring of claim 1, wherein a top surface of the upper horizontal section includes a plurality of holes, each hole of the plurality of holes is configured to receive a portion of a fastener means for securing the confinement ring to an upper electrode of a plasma processing chamber.

8. The confinement ring of claim 1, wherein the extension section of the lower horizontal section is configured to rest on a radio frequency gasket defined on a top surface of a lower electrode of a plasma processing chamber.

9. The confinement ring of claim 1, wherein the lower horizontal section, the vertical section and the upper horizontal section define a C-shaped structure for confining plasma generated in a plasma processing chamber.

10. The confinement ring of claim 1, wherein a ratio of the inner slot radius to the outer slot radius is between about 1:1.1 and 1:1.5.

11. An apparatus for confining plasma within a plasma processing chamber, the plasma processing chamber includes a lower electrode for supporting a substrate and an upper electrode disposed over the lower electrode, the apparatus comprising,
a confinement ring, including,
a lower horizontal section extending between an inner lower radius and an outer radius of the confinement ring, the lower horizontal section includes an extension section that extends vertically downward at the inner lower radius, the lower horizontal section includes a plurality of slots, wherein each slot extends radially from an inner diameter to an outer diameter along the lower horizontal section, an inner slot radius of each slot at the inner diameter is less than an outer slot radius of each slot at the outer diameter;
an upper horizontal section extending between an inner upper radius and the outer radius of the confinement ring; and
a vertical section that integrally continues the lower horizontal section to the upper horizontal section at the outer radius of the confinement ring,
wherein the extension section of the lower horizontal section is configured to surround a ground ring defined in the lower electrode.

12. The apparatus of claim 11, wherein the lower horizontal section, the vertical section and the upper horizontal section of the confinement ring define a C-shaped structure to confine plasma generated in the plasma processing chamber to a plasma region defined between the upper electrode and the lower electrode of the plasma processing chamber.

13. The apparatus of claim 11, wherein the inner upper radius is greater than the inner lower radius of the confinement ring.

14. The apparatus of claim 11, wherein a step is defined on a top surface proximate to the inner upper radius of the upper horizontal section, the step extending from the top surface down and outward toward the inner upper radius of the confinement ring.

15. The apparatus of claim 11, wherein a top surface of the upper horizontal section includes a plurality of holes, each hole of the plurality of holes configured to receive a portion of a fastener means, the fastener means configured to couple the confinement ring to an extension of the upper electrode, wherein the extension of the upper electrode is electrically grounded.

16. The apparatus of claim 11, wherein the extension section of the lower horizontal section is configured to rest on a radio frequency gasket disposed on a top surface of an outer ring disposed adjacent to a ground ring defined in the lower electrode.

17. The apparatus of claim 11, wherein the confinement ring defined by the lower horizontal section, the upper horizontal section and the vertical section is a continuous structure made from one of silicon, or polysilicon, or silicon carbide, or boron carbide, or ceramic, or aluminum.

18. The apparatus of claim 11, wherein a height of the vertical section of the confinement ring is defined by a separation distance defined between the upper electrode and the lower electrode of the plasma processing chamber, when the plasma processing chamber is engaged for plasma processing.

19. The apparatus of claim 11, wherein the lower horizontal section, the upper horizontal section and the vertical section of the confinement ring form part of a confined chamber volume that extends radially outward between the lower electrode and upper electrode to define extended plasma processing region, when said confinement ring is installed in said plasma processing chamber.

20. The apparatus of claim 11, wherein the extension section is integral with the lower horizontal section, the vertical section and the upper horizontal section of the confinement ring, the extension section configured to extend below a lower surface of the lower horizontal section.

21. The apparatus of claim 11, wherein each of the plurality of slots defines a path for gases out of a confined volume formed by the confinement ring, when the plasma processing chamber is in operation.
